(19) United States
(12) Patent Application Publication
(10) Pub. No.: US 2022/0172995 A1
(43) Pub. Date: Jun. 2, 2022

(54) CHIP MANUFACTURING METHOD

(71) Applicant: Panasonic Intellectual Property Management Co., Ltd., Osaka (JP)

(72) Inventor: Hiroshi BENNO, OSAKA (JP)

(21) Appl. No.: 17/528,320

(22) Filed: Nov. 17, 2021

(30) Foreign Application Priority Data
Nov. 27, 2020 (JP) 2020-197567

(51) Int. Cl. H01L 21/822; H01L 21/3065

(52) U.S. Cl. CPC H01L 21/822; H01L 21/30655

(57) ABSTRACT

The chip manufacturing method includes: a preparing step of preparing a substrate 1 having a plurality of elements 2; a defining step of defining, based on information regarding a satisfactory element 2a and/or a defective element 2b, an arrangement of chips 10 each composed of two or more adjacent ones of the elements 2 such that the number of the chips 10 that include only the satisfactory elements 2a is larger than in the case of dividing the substrate 1 into a plurality of the chips 10 along virtual dicing lines formed assuming that the defective element 2b does not exist; a mask forming step of forming, based on the defined arrangement of the chips 10, a mask 20 that has openings 20a and that covers the chips 10; and a dividing step of dividing the substrate 1 into a plurality of the chips 10 by plasma etching.

### CROSS REFERENCE TO RELATED APPLICATION

The present application is based on and claims priority under 35 U.S.C. § 119 with respect to the Japanese Patent Application No. 2020-197567 filed on Nov. 27, 2020, of which entire content is incorporated herein by reference into the present application.

### TECHNICAL FIELD

The present disclosure relates to a chip manufacturing method.

### BACKGROUND

Conventionally, methods for manufacturing chips by plasma dicing a semiconductor wafer have been known (e.g., Japanese Laid-Open Patent Publication (Translation of PCT Application) No. 2014-513868). In the method according to Japanese Laid-Open Patent Publication (Translation of PCT Application) No. 2014-513868, plasma dicing is performed in a vacuum processing chamber in a state in which device structures of a wafer are covered with a protection film, while street regions of the wafer are exposed. Consequently, the wafer is divided at the street regions, and a plurality of chips each including a device structure are obtained.

### SUMMARY

Meanwhile, in chip manufacturing, one chip including a plurality of elements may be produced in order to increase the output of chips. In such a case, if even one element determined as a defective product (hereinafter referred to as a “ defective element”) exists in the plurality of elements included in a chip, the entire chip needs to be processed as a defective product. This directly leads to a reduction in the yield in chip manufacturing. Under such circumstances, it is an object of the present disclosure to improve the yield in chip manufacturing.

An aspect of the present disclosure relates to a chip manufacturing method. The chip manufacturing method includes: a preparing step of preparing a substrate on which a plurality of elements are formed; a defining step of defining an arrangement of chips each composed of two or more adjacent ones of the elements, the arrangement of chips being defined based on information regarding at least one of a satisfactory element and a defective element that are included in the plurality of elements, such that the number of the chips that include only the satisfactory elements is larger than in the case of dividing the substrate into a plurality of the chips along virtual dicing lines formed assuming that the defective element does not exist; a mask forming step of forming, based on the defined arrangement of the chips, a mask that has openings to expose the substrate along a periphery of each of the chips and that covers the chips; and a dividing step of dividing the substrate into a plurality of the chips by plasma etching the substrate.

According to the present disclosure, it is possible to improve the yield in chip manufacturing.

### BRIEF DESCRIPTION OF THE DRAWINGS

FIG. 1 is flowchart showing a chip manufacturing method according to an embodiment of the present disclosure.

FIG. 2 is a diagram showing a substrate, showing virtual dicing lines before a defining step is performed.

FIG. 3 is a diagram showing a substrate, showing actual dicing lines after the defining step has been performed.

FIG. 4 is a cross-sectional view showing a substrate on which a protection film has been formed by a protection film forming step.

FIG. 5 is a cross-sectional view showing a substrate on which a mask has been formed by a protection film removing step.

FIG. 6 is a cross-sectional view showing a plurality of chips formed by a dividing step.

FIG. 7 is a cross-sectional view showing the chips from which the mask has been removed by a washing step.

FIG. 8 is a diagram showing an example of a plasma etching apparatus.

### DETAILED DESCRIPTION

An embodiment of the method for manufacturing an element chip according to the present disclosure will be described below by way of examples. However, the present disclosure is not limited to the examples described below. Although examples of specific numerical values and materials may be given in the following description, other numerical values and materials may be used as long as the effects of the present disclosure can be achieved.

### Chip Manufacturing Method

A chip manufacturing method according to the present disclosure includes a preparing step, a defining step, a mask forming step, and a dividing step. These steps will be described below.

### Preparing Step

In the preparing step, a substrate on which a plurality of elements are formed is prepared. The elements may each be, for example, but is not limited to, a laser diode element or an LED element. The substrate may be a semiconductor substrate having any shape, including, for example, a circular shape or a rectangular shape.

### Defining Step

In the defining step, an arrangement of chips each composed of two or more adjacent ones of the elements is defined, the arrangement of chips being defined based on information about at least one of a satisfactory element (meaning an element that is satisfactory; the same applies to the following) and a defective element that are included in the plurality of elements, such that the number of the chips (hereinafter also referred to as “satisfactory chips”) that include only the satisfactory elements is larger than in the case of dividing the substrate into a plurality of the chips along virtual dicing lines formed assuming that the defective element does not exist. The defining step may be performed based only on the information about the satisfactory element, or only on the information about the defective element, or on both the information about the satisfactory element and the information about the defective element.

The arrangement of the elements in each of the chips can be freely set. For example, a 1×2 element arrangement, a 2×2 element arrangement, or a 2×3 element arrangement are conceivable. The larger the number of elements included in each chip, the higher the output (the brightness, the rated current, etc.) of that chip is.

### Mask Forming Step

In the mask forming step, a mask that has openings to expose the substrate along a periphery of each of the chips and that covers the chips is formed based on the arrangement of the chips that has been defined in the defining step. The mask may be formed by applying a mask material onto the entire surface of the substrate using a method such as spin coating or spray coating, and thereafter patterning the resulting coating film. When the mask material is photoresist, a photolithography technique through exposure and development can be used as the patterning method. Although exposure can be performed by one-shot exposure by which the entire substrate is exposed at once, exposure by rendering or exposure using a stepper is preferable in terms of the ease of responding to the change of the chip arrangement. When the mask material is a water-soluble resin or the like, patterning may be performed by laser grooving. Alternatively, the mask may be formed by selectively applying a mask material onto the chip regions by using a method such as spray coating.

### Dividing Step

In the dividing step, the substrate is divided into a plurality of the chips by plasma etching the substrate. In the dividing step, portions of the substrate that are exposed through the openings of the mask are plasma etched. For plasma etching, it is possible to use, for example, a Bosch process or a non-Bosch process.

Here, depending on the arrangement of the chips that is defined in the defining step, the shape of the opening regions (dicing lines) surrounding each satisfactory chip may be more complex than that of an ordinary lattice configuration. When the dicing lines are not linear, it is difficult to divide the substrate using a blade. One of a dividing method that can cope with such complex dicing lines is laser dicing by which the substrate is divided while the dicing lines are traced with laser. However, in the case of dividing the substrate while tracing the dicing lines, as in the case of laser dicing, the substrate is irradiated with laser light having a relatively high intensity that is required to divide the substrate. Accordingly, the substrate tends to receive a greater damage in the vicinity of an intersection where the lines of the dicing lines intersect each other, or in the vicinity of bent portions of the dicing lines. This may pose problems for the satisfactory chips, such as thermal effects, attachment of debris, and a reduction in the shape accuracy.

In contrast, in the dividing step according to the present disclosure, the mask is formed on the surface of the substrate in the mask forming step, and thereafter the substrate is divided into a plurality of chips by plasma etching. Since plasma etching enables dicing to be performed on the entire substrate at once, the above-described problems due to the complex shape of the dicing lines around the satisfactory chips do not occur. That is, the dividing step according to the present disclosure is very effective in preventing the occurrence of problems that could be caused by the defining step unique to the present disclosure.

As described above, according to the present disclosure, chips including only satisfactory elements can be produced as much as possible from one substrate, and it is therefore possible to improve the yield in chip manufacturing.

The mask forming step may include a protection film forming step of forming a protection film so as to cover the substrate; and a protection film removing step of removing, based on the defined arrangement of the chips, the protection film covering a periphery of each of the chips, to form the openings.

In the protection film removing step, the protection film covering the periphery of each of the chips may be removed by irradiating the protection film with laser light. That is, the so-called laser grooving may be used for removing the protection film. Even when the protection film is made of a material other than photoresist, which can be patterned by photolithography, such as a water-soluble resin, the protection film can be removed by using laser grooving.

Although harmful effects of laser dicing, which uses laser light in the dividing step, have been described above, the laser light intensity required to remove the protection film is lower than the laser light intensity required to divide the substrate in the case of using laser light in the protection film removing step. Accordingly, abnormality in the processed shape (opening shape) of the protection film is less likely to occur in the vicinity of intersection where the dicing lines intersect each other, or in the vicinity of bent portions of the dicing lines, and the substrate receives less damage due to removal of the protection film.

When the protection film is composed of photoresist, the protection film covering the periphery of each of the chips may be removed by exposing a portion of the protection film. Although exposure can be performed by one-shot exposure by which the entire substrate is exposed at once, exposure by rendering with laser light or an electron beam, or exposure using a stepper is preferable in terms of the ease of responding to the change of the chip arrangement.

The chip manufacturing method may further include, after the dividing step, a washing step of removing the mask remaining on a surface of the chips by bringing the mask into contact with a liquid that dissolves the mask. This makes it possible to easily remove the remaining mask. In addition, even when any foreign substance is attached to the mask surface during the dividing step, the attached foreign substance can be easily removed together with the remaining mask. Note that the mask remaining on the chip surface may be removed by ashing.

The mask may have water solubility, and the liquid may include water. Note that the mask need not have water solubility, and the liquid may include an organic solvent that dissolves the mask.

In the following, an exemplary chip manufacturing method according to the present disclosure will be described in detail with reference to the drawings. The above-described steps can be applied to the steps of the exemplary chip manufacturing method described below. The steps of the exemplary chip manufacturing method described below can be changed based on the above description. The matters described below may be applied to the above-described embodiment. Of the steps of the exemplary chip manufacturing method described below, steps that are not essential to the chip manufacturing method according to the present disclosure may be omitted. Note that the drawings described below are schematic views, and do not accurately reflect the actual shapes and the actual numbers of components.

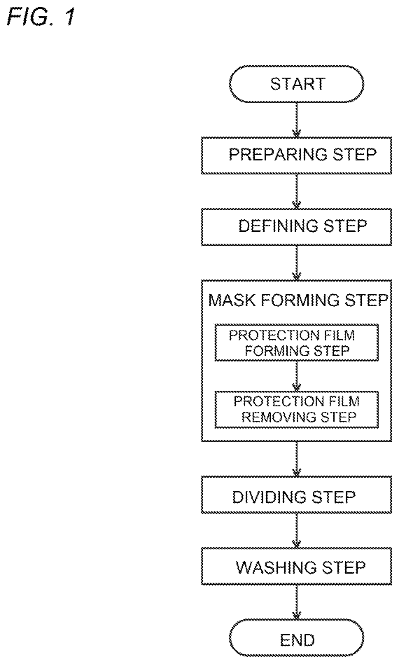

As shown in FIG. 1, the chip manufacturing method includes a preparing step, a defining step, a mask forming step, a dividing step, and a washing step.

### Preparing Step

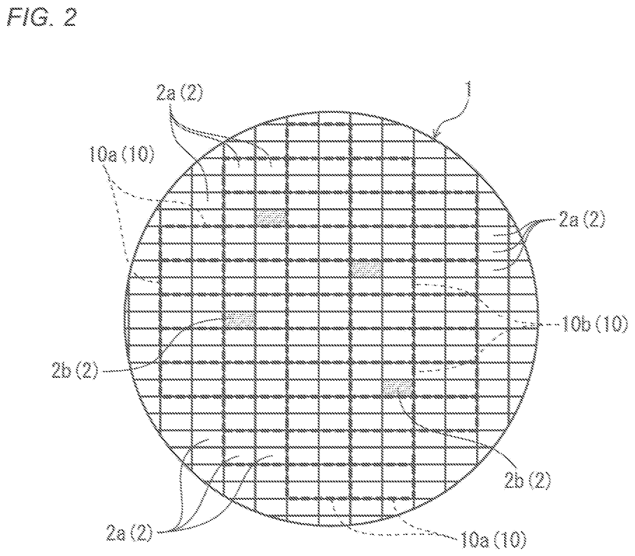

In the preparing step, as shown in FIG. 2, a substrate 1 on which a plurality of elements 2 are formed is prepared. The substrate 1 according to the present embodiment is a substantially circular silicon semiconductor substrate. However, the present disclosure is not limited thereto. The plurality of elements 2 include satisfactory elements 2a constituting a majority of the elements 2, and a smaller number of (in this example, four) defective elements 2b (indicated by dark hatching in FIG. 2). The determination as to whether each element 2 is satisfactory or defective can be performed by a known method, including, for example, a method in which the electrical characteristics of each element 2 are measured.

In FIG. 2, virtual dicing lines formed assuming that the defective element 2b does not exist are indicated by the bold dashed lines. The virtual dicing lines may be in a lattice configuration (grid configuration) composed of a plurality of vertical dicing lines and a plurality of horizontal dicing lines that are not bent midway. With the virtual dicing lines, 42 chips 10 each including 2 x 2 elements 2 can be produced from one substrate 1. However, the defective elements 2b indicated by the dark hatching exist at the illustrated positions. Accordingly, 4 chips 10 are defective chips 10b (meaning chips 10 each including any defective element 2b), so that 38 chips can be actually produced as the satisfactory chips 10a. Therefore, in the present embodiment, the number of satisfactory chips that can be produced from one substrate 1 is increased by performing the defining step described in the following. Note that the number of elements 2 and the number of chips 10 shown in this paragraph are merely illustrative.

### Defining Step

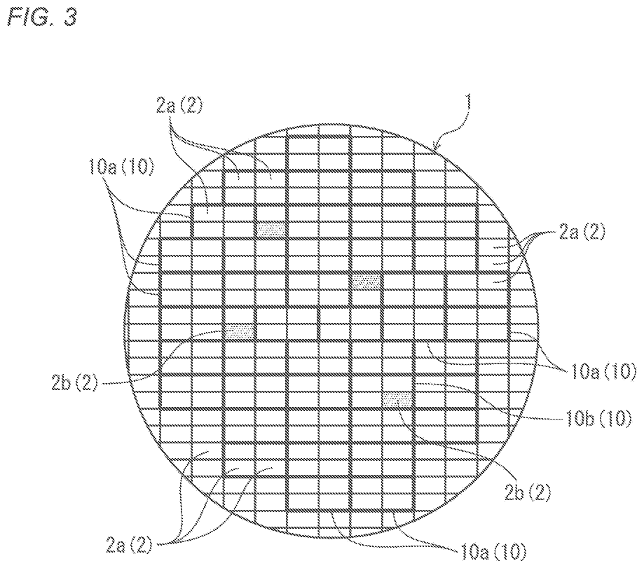

In the defining step, an arrangement of chips 10 each composed of two or more adjacent ones of the elements 2 is defined, the arrangement of chips being defined based on information about at least one of a satisfactory element 2a and a defective element 2b that are included in the plurality of elements 2, such that the number of satisfactory chips 10a is larger than in the case of dividing the substrate 1 into a plurality of the chips 10 along virtual dicing lines formed assuming that the defective element 2b does not exist. In the defining step according to the present embodiment, as shown in FIG. 3, the arrangement of the chips 10 is defined by determining actual dicing lines (thick solid lines). For the defining processing, any suitable algorithm can be used. With the actual dicing lines, 41 satisfactory chips 10a each including 2×2 elements 2 can be produced from one substrate 1.

In the defining step, it is preferable that the arrangement of the chips 10 each composed of two or more adjacent ones of the elements 2 is defined such that the number of satisfactory chips 10a is maximum, based on information about at least one of the satisfactory element 2a and the defective element 2b that are included in the plurality of elements 2.

### Mask Forming Step

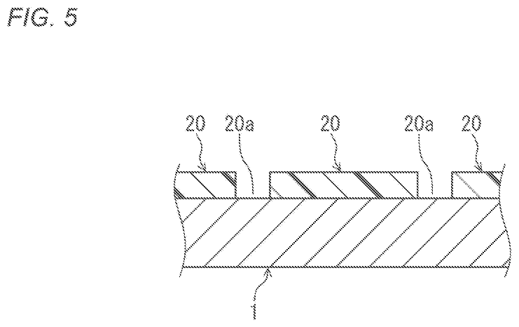

In the mask forming step, based on the arrangement of the chips 10 that has been defined in the defining step, a mask 20 (see FIG. 5) that has openings 20a to expose the substrate 1 along the periphery of each of the chips 10 and that covers the chip 10 is formed. The mask forming step includes a protection film forming step and a protection film removing step.

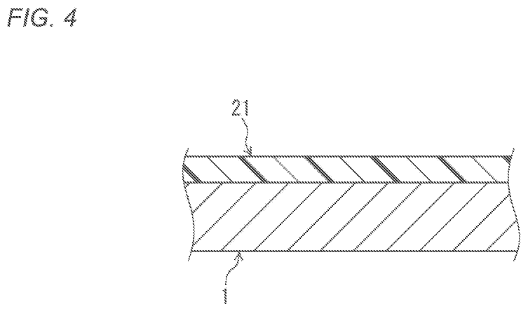

In the protection film forming step, as shown in FIG. 4, a protection film 21 is formed so as to cover the substrate 1. The protection film 21 may be formed using a known coating method such as spray coating or spin coating, and a known drying method such as heating. Alternatively, the protection film 21 may be constituted by a resin film attached to the substrate 1. The constituent material of the protection film 21 of the present embodiment is a water-soluble resin material. However, the constituent material is not limited thereto, and may be photoresist, for example.

In the protection film removing step, as shown in FIG. 5, the protection film 21 covering the periphery of each of the chips 10 is removed by irradiating the protection film 21 with laser light (not shown), based on the arrangement of the chips 10 that has been defined in the defining step. Consequently, a water-soluble mask 20 that has openings 20a to expose the substrate 1 along the periphery of each of the chips 10 is formed. As the laser light source, it is possible to use, for example, a nanosecond laser with a UV wavelength (e.g., 355 nm).

### Dividing Step

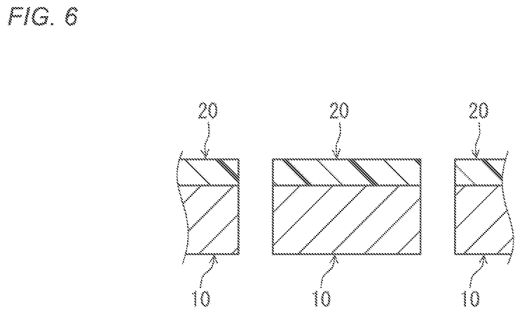

In the dividing step, as shown in FIG. 6, the substrate 1 is divided into a plurality of the chips 10 by plasma etching the substrate 1.

From the viewpoint of handleability, it is preferable that the substrate 1 is attached, via an adhesive layer, to a holding sheet fixed to a frame. A member including the frame and the holding sheet fixed to the frame is referred to as a “ transport carrier”.

The frame is a frame body having an opening sized to surround a plurality of electronic components, and has a predetermined width and a substantially constant small thickness. The frame has a rigidity sufficient to be able to transport the holding sheet and the substrate 1 while holding the holding sheet and the substrate 1. The shape of the opening of the frame is not particularly limited, and may be, for example, a circular shape, or a polygonal shape such as a rectangular shape or a hexagonal shape. Examples of the material of the frame include metal such as aluminum and stainless steel, and resin.

The material of the holding sheet is not particularly limited. In particular, from the viewpoint of ease of attachment of the substrate 1, it is preferable that the holding sheet includes an adhesive layer and a non-adhesive layer having flexibility.

The material of the non-adhesive layer is not particularly limited, and examples thereof include thermoplastic resins, including, for example, polyolefins such as polyethylene and polypropylene, polyvinyl chloride, and polyesters such as polyethylene terephthalate. Various additives such as a rubber component (e.g., an ethylene-propylene rubber (EPM), an ethylene-propylene-diene rubber (EPDM) etc.) for providing stretchability, a plasticizer, a softening agent, an antioxidant, and a conductive material may be blended in the resin film. The above-described thermoplastic resin may include a functional group exhibiting photopolymerization reaction, such as an acrylic group. The thickness of the non-adhesive layer is not particularly limited, and is, for example, 50 μm or more and 300 μm or less, and preferably 50 μm or more and 150 μm or less.

A peripheral edge of a surface (adhesive surface) including the adhesive layer is attached to one surface of the frame, and covers the opening of the frame. The substrate is attached to a portion of the adhesive surface that is exposed through the opening of the frame. Preferably, the adhesive layer is made of an adhesive component whose adhesive force is reduced by irradiation with ultraviolet light (UV). This allows the chips 10 to be easily separated from the adhesive layer by performing UV irradiation when picking up the chips 10 after the dividing step, thus facilitating the pick-up. For example, the adhesive layer can be obtained by applying, onto one surface of the non-adhesive layer, a UV-curable acrylic adhesive agent in a thickness of 5 μm or more and 100 μm or less (preferably 5 μm or more and 15 μm or less).

The dividing step and an exemplary plasma etching apparatus used in the dividing step will be described below.

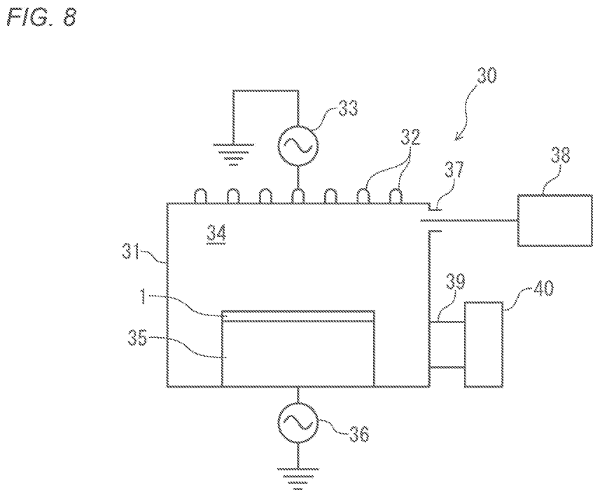

As shown in FIG. 8, a dielectric window (not shown) is provided at the top of a chamber 31 of a plasma etching apparatus 30. An antenna 32 serving as an upper electrode is disposed above the dielectric window. The antenna 32 is electrically connected to a first high-frequency power supply section 33. On the other hand, a stage 35 on which a substrate 1 fixed to a transport carrier (not shown) is to be disposed is disposed on the bottom side of a processing room 34 in the chamber 31. The stage 35 also functions as a bottom electrode, and is electrically connected to a second high-frequency power supply section 36. The stage 35 includes an electrostatic chucking electrode (ESC electrode), which is not shown, and the substrate 1 that is fixed to the transport carrier placed on the stage 35 can be electrostatically chucked to the stage 35. A gas introduction port 37 of the chamber 31 is fluidly connected to an etching gas source 38. An exhaust port 39 of the chamber 31 is connected to a vacuum evacuation section 40 including a vacuum pump for vacuum evacuating the chamber 31.

After the substrate 1 has been placed on the stage 35 in the chamber 31, the pressure inside the chamber 31 is reduced using the vacuum pump of the vacuum evacuation section 40, and a predetermined process gas is introduced into the chamber 31. Then, the substrate 1 in the chamber 31 is plasma etched with a plasma of the process gas that has been formed by supplying high-frequency power to the antenna 32 (plasma source), and the substrate 1 is divided into a plurality of chips 10, as shown in FIG. 6.

### Washing Step

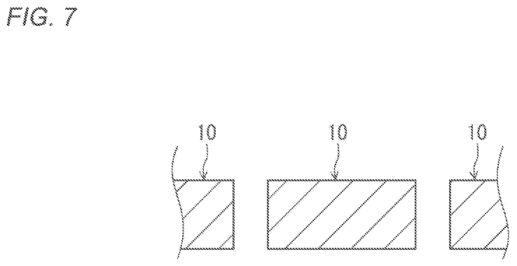

In the washing step, as shown in FIG. 7, the mask 20 remaining on the surface of the chips 10 is removed by being brought into contact with a liquid (in this example, water or a liquid containing water) that dissolves the mask 20. In the washing step, the mask 20 may be removed by spraying the aforementioned liquid to the mask 20 using a spray or the like. This can also wash off any debris attached to the chip 10.

The present disclosure is applicable to a chip manufacturing method.

### REFERENCE NUMERALS

1: Substrate
2: Element
2a: Satisfactory element
2b: Defective element

10: Chip

10a: Satisfactory chip

10b: Defective chip

20: Mask
20a: Opening

21: Protection film

30: Plasma etching apparatus
31: Chamber
32: Antenna
33: First high-frequency power supply section
34: Processing room
35: Stage
36: Second high-frequency power supply section
37: Gas introduction port
38: Etching gas source
39: Exhaust port
40: Vacuum evacuation section

What is claimed is:

1. A chip manufacturing method comprising:
a preparing step of preparing a substrate on which a plurality of elements are formed;
a defining step of defining an arrangement of chips each composed of two or more adjacent ones of the elements, the arrangement of chips being defined based on information regarding at least one of a satisfactory element and a defective element that are included in the plurality of elements, such that the number of the chips that include only the satisfactory elements is larger than in the case of dividing the substrate into a plurality of the chips along virtual dicing lines formed assuming that the defective element does not exist;
a mask forming step of forming, based on the defined arrangement of the chips, a mask that has openings to expose the substrate along a periphery of each of the chips and that covers the chips; and
a dividing step of dividing the substrate into a plurality of the chips by plasma etching the substrate.

2. The chip manufacturing method according to claim 1,
wherein the mask forming step includes:
a protection film forming step of forming a protection film so as to cover the substrate; and
a protection film removing step of removing, based on the defined arrangement of the chips, the protection film covering a periphery of each of the chips, to form the openings.

3. The chip manufacturing method according to claim 2,
wherein, in the protection film removing step, the protection film covering the periphery of each of the chips is removed by irradiating the protection film with laser light.

4. The chip manufacturing method according to claim 1, further comprising,
after the dividing step, a washing step of removing the mask remaining on a surface of the chips by bringing the mask into contact with a liquid that dissolves the mask.

5. The chip manufacturing method according to claim 4,
wherein the mask has water solubility, and
the liquid includes water.
